(19) United States
(12) Patent Application Publication
(10) Pub. No.: US 2026/0008671 A1
(43) Pub. Date: Jan. 8, 2026

(54) DROP TEST DEVICE FOR A MICROMECHANICAL COMPONENT

(71) Applicant: Robert Bosch GmbH, Stuttgart (DE)

(72) Inventor: Manuel Dietrich, Reutlingen (DE)

(21) Appl. No.: 19/252,172

(22) Filed: Jun. 27, 2025

(30) Foreign Application Priority Data
Jul. 5, 2024 (DE) 10 2024 206 346.0

(51) Int. Cl. B81C 99/00; G01N 3/303

(52) U.S. Cl. CPC B81C 99/005; G01N 3/303; B81C 2201/05; G01N 2203/001; G01N 2203/0033

(57) ABSTRACT

A drop test device for a micromechanical component. The drop test device includes a drop body having a shell and having an interior space for receiving at least one micromechanical component.

### CROSS REFERENCE

The present application claims the benefit under 35 U.S.C. § 119 of German Patent Application No. DE 10 2024 206 346.0 filed on Jul. 5, 2024, which is expressly incorporated herein by reference in its entirety.

### BACKGROUND INFORMATION

For ascertaining the mechanical robustness of MEMS sensors, drop tests are performed in the related art. Normally, unsoldered sensors are dropped from a height of, for example, 2 m onto a plate, for example a plate made of granite. As a result, the movable MEMS structure is deflected in a random direction and, in this random direction, strikes the fixed elements of the MEMS. Subsequently, it is ascertained by means of electrical measurement of the sensors whether the sensor signals indicate a mechanical defect. In the event of a fault, the sensor core is technically analyzed for mechanical defects by using imaging techniques (for example, infrared or SEM). Based on the individual damage, design optimizations of the MEMS can then be performed.

In the case of sensors that are packaged in a chip housing, for example a chip housing made of plastics material, the actual MEMS sensor made of silicon does not have direct contact with the plate on the ground during the drop test. In the case of MEMS sensors arranged in a chip-scale package, the silicon of the MEMS and the ASIC is unprotected from the outside. If the silicon directly impacts the hard plate, severe damage to the outer shell of the sensor can occur, which damage obscures the actual objective of the test, namely to provoke damage to the internal moving micromechanical structures.

### SUMMARY

An object of the present invention is to provide a drop test device for a micromechanical (MEMS) component, which device is designed to subject the MEMS component to a free-fall impact without damaging it externally.

The present invention relates to a drop test device for a micromechanical component. According to an example embodiment of the present invention, the drop test device includes a drop body having a shell and having an interior space for receiving at least one micromechanical component.

In order to examine micromechanical components in an undirected drop test, they are placed according to the present invention in a drop body, for example a drop body made of plastics material. This prevents mechanical damage to the outer shell.

In particular in the case of micromechanical components in a chip-scale package, mechanical damage to the exposed silicon substrates is advantageously prevented.

An advantageous example embodiment of the present invention provides that the micromechanical component can be placed in the interior space and can be connected to the shell in a form-fitting and/or force-fitting manner. This advantageously protects the component from hard impact on a surface.

Nevertheless, the shock caused by the impact of the drop body on a hard surface is transferred to the micromechanical structures inside the MEMS component.

An advantageous example embodiment of the present invention provides that the drop body is spherical. As a result, chaotic impact scenarios are advantageously avoided.

An advantageous example embodiment of the present invention provides that the shell is composed of two hemispheres. Advantageously, the micromechanical component can thus be placed in the center of the drop body, in the interior space formed by a recess in the hemispheres.

An advantageous example embodiment of the present invention provides that a test board for receiving the micromechanical component is arranged in the interior space and that the micromechanical component can be connected to the test board in a form-fitting and/or force-fitting and/or materially-bonded manner. Advantageously, the micromechanical component is mounted on the test board in the same way as in the later application on a printed circuit board having a similar fastening and shock load upon impact. Advantageously, the micromechanical component is only fastened to the test board, so that the remaining interior space can be freely designed and micromechanical components of different sizes and shapes can be positioned therein, as long as they are only fastened to the test board. On the one hand, avoiding external damage makes the actual drop test, or rather the impact test for components in chip-scale packages, possible in the first place. On the other hand, a further aspect of the previous test is thus significantly improved: previously, impacts on a sensor's edge or corner could produce strong moments that depended not only on the operator of the machine (such as the sensor's orientation and initial rotation at the point of release), but also could not be simulated or predicted due to their chaotic nature and randomness.

Due to the radially uniform distribution of impact points on the surface of the sphere and the center of mass located in the middle of the sphere, chaotic impact scenarios are minimized and the test becomes easier to simulate. This has the advantage that potential damage to the MEMS structures can be better understood and thus compared with alternative designs.

### BRIEF DESCRIPTION OF THE DRAWINGS

FIG. 1 schematically shows a micromechanical device in an LGA package in the related art.

FIG. 2 schematically shows a micromechanical device in a bare-die chip-scale package in the related art.

FIG. 3 schematically shows a drop test device according to the present invention in the form of a spherical drop body in a first exemplary embodiment.

FIG. 4 schematically shows a drop test device according to the present invention in the form of a spherical drop body in a second exemplary embodiment.

### DETAILED DESCRIPTION OF EXAMPLE EMBODIMENTS

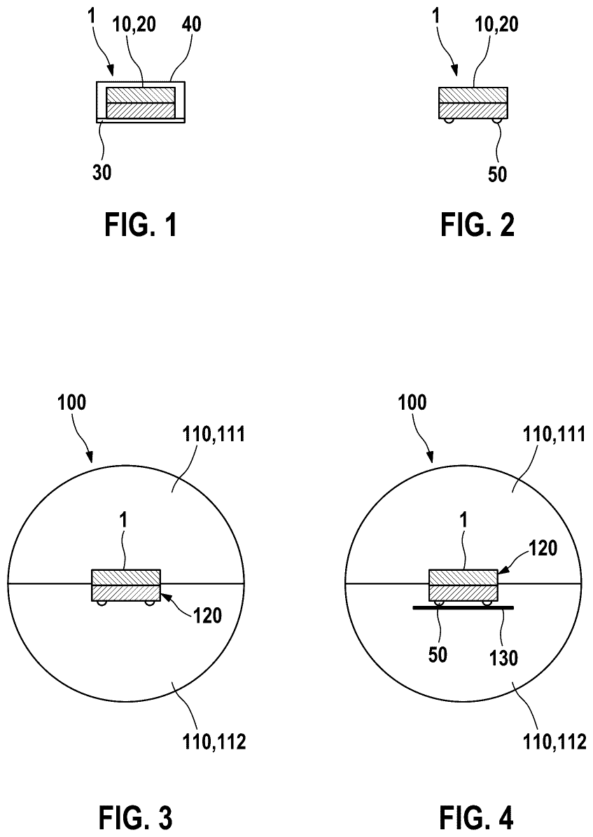

FIG. 1 schematically shows a micromechanical device in an LGA package in the related art. An ASIC chip 10 and a micromechanical (MEMS) chip 20 are stacked on top of one another and surrounded by a substrate printed circuit board (PCB) 30 at the bottom and encapsulation material 40 at the top and sides. Solder balls 50 are arranged on the underside of the printed circuit board. A drop test of a MEMS component packaged in this way leaves only minor traces, if any.

FIG. 2 schematically shows a micromechanical device in a bare-die chip-scale package in the related art. The stacked silicon substrates of MEMS chip 20 and ASIC chip 30 are exposed. In a drop test of a MEMS component packaged in this manner, impact with a hard surface can cause damage to the silicon, such as chip fractures or chipping at the chip surface, in particular at corners and edges.

FIG. 3 schematically shows a drop test device according to the present invention in the form of a spherical drop body in a first exemplary embodiment. The drop test device comprises a drop body 100 having a shell 110 and having an interior space 120 for receiving a micromechanical component 1. The figure shows a micromechanical component in a chip-scale package, installed in a drop body 100 having a shell 110 in the form of a sphere consisting of two hemispheres 111, 112. The drop body is designed to fall freely and impact a base. The micromechanical component is mounted in the drop body and protected by the shell. When the drop body impacts the base, the micromechanical component therefore experiences the impact event without external damage.

FIG. 4 schematically shows a drop test device according to the present invention in the form of a spherical drop body in a second exemplary embodiment. The figure shows a micromechanical component 1 in a chip-scale package, soldered by means of solder balls 50 on a test board 130 in a sphere consisting of two hemispheres 111, 112. The micromechanical component is mounted on the test board in the drop body and protected by the shell.

### LIST OF REFERENCE SIGNS

1 Micromechanical component
10 ASIC chip
20 Micromechanical (MEMS) chip
30 Substrate printed circuit board (PCB)
40 Encapsulation material
50 Solder balls
100 Drop body
110 Shell
111, 112 Hemispheres
120 Interior space
130 Test board

What is claimed is:

1. A drop test device for a micromechanical component, comprising:
a drop body including a shell and an interior space configured to receive at least one micromechanical component.

2. The drop test device according to claim 1, wherein the micromechanical component can be placed in the interior space and can be connected to the shell in a form-fitting and/or force-fitting manner.

3. The drop test device according to claim 1, wherein the drop body is spherical.

4. The drop test device according to claim 3, wherein the shell includes two hemispheres.

5. The drop test device according to claim 1, further comprising:
a test board configured to receive the micromechanical component, and being arranged in the interior space, wherein the micromechanical component can be connected to the test board in a form-fitting and/or force-fitting and/or materially-bonded manner.
